(19) United States
(12) Patent Application Publication
(10) Pub. No.: US 2012/0057308 A1
(43) Pub. Date: Mar. 8, 2012

(54) Modular Stacked Power Converter Vessel

(75) Inventor: Christof Martin Sihler, Garching (DE)

(73) Assignee: GENERAL ELECTRIC COMPANY, Schnectady, NY (US)

(21) Appl. No.: 12/875,175

(22) Filed: Sep. 3, 2010

(51) Int. Cl. H05K 7/00; B65D 85/00

(52) U.S. Cl. 361/730; 206/320

(57) ABSTRACT

The present application provides a modular stacked power converter vessel. The modular stacked power converter vessel may include an inner container at a first potential, a modular stacked power converter positioned within the inner container, and an outer container. The outer container surrounds the inner container and may be at a second potential.

### TECHNICAL FIELD

The present application relates generally to electrical power deliver systems and more particularly relates to modular stacked power converter vessels for sub-sea power delivery by direct current (DC) power transmission.

### BACKGROUND OF THE INVENTION

Transportation of electrical power to, for example, oil, gas, or other types of sub-sea electrical equipment, often requires low or high power to be transported over any type of distance to serve one or multiple loads. Electrical power delivery systems for offshore or sub-sea electrical loads generally use a DC (direct current) transmission bus or cable. The receiving end and the sending end of the DC transmission bus may include modular stacked power converters that are largely symmetrical in structure. The configuration of the modular stacked power converters preferably may be expandable and reconfigurable based upon local load requirements and changes.

In modular stacked high voltage DC power transmission and distribution topologies, DC to AC (alternating current) converter modules and the like may be designed for a nominal DC voltage of a few kilovolts, e.g., only about five (5) kilovolts. These modules, however, also may need to be insulated for high voltages, e.g., about fifty (50) kilovolts against the ground potential. This requirement may be difficult to fulfill with typical high voltage engineering designs where all metallic screens or vessels are typically at one potential, e.g., ground potential. Much more electrical insulation space may be required with the typical complex and multipart converter designs. As a result, complex sub-sea converter systems cannot be efficiently marinized or optimized from a high voltage engineering design point of view.

There is thus a desire for optimized packaging and grounding systems and methods for modular stacked high voltage, direct current power transmission systems for sub-sea use. Such systems and methods may provide optimum power delivery with low system costs and complexity, high system reliability and maintainability, high efficiency, and high power density.

### SUMMARY OF THE INVENTION

The present application thus provides a modular stacked power converter vessel. The modular stacked power converter vessel may include an inner container at a first potential, a modular stacked power converter positioned within the inner container, and an outer container. The outer container surrounds the inner container and may be at a second potential.

The present application further provides a modular stacked power converter vessel. The modular stacked power converter vessel may include an inner container, a modular stacked power converter positioned within the inner container, and an outer container surrounding the inner container. The modular stacked power converter may have a converter potential and the inner container may have about the converter potential. The outer container may have a ground potential.

The present application further provides a marinized high voltage direct current system for sub-sea DC power transmission and distribution. The marinized high voltage direct current system may include a first module at a first potential, a second module at a second potential, and an electrical connection between the first module and the second module. The first module and the second module both may include a number of modular stacked power converters therein. Each of the modular stacked power converters may be positioned within a modular stacked power converter vessel. The modular stacked power converter vessel may include an inner container within an outer container.

These and other features and improvements of the present application will become apparent to one of ordinary skill in the art upon review of the following detailed description when taken in conjunction with the several drawings and the appended claims.

### BRIEF DESCRIPTION OF THE DRAWINGS

FIG. 1 is a schematic view of the onshore and sub-sea components of a marinized high power HVDC (High Voltage Direct Current) system.

FIG. 2 is a schematic view of the onshore and sub-sea components of a marinized low power HVDC system.

FIG. 3 is a schematic view of a number of modular stacked power converter vessels arranged for unipolar HVDC transmission.

FIG. 4 is a schematic view of a number of modular stacked power converter vessels arranged for bipolar HVDC transmission.

### DETAILED DESCRIPTION

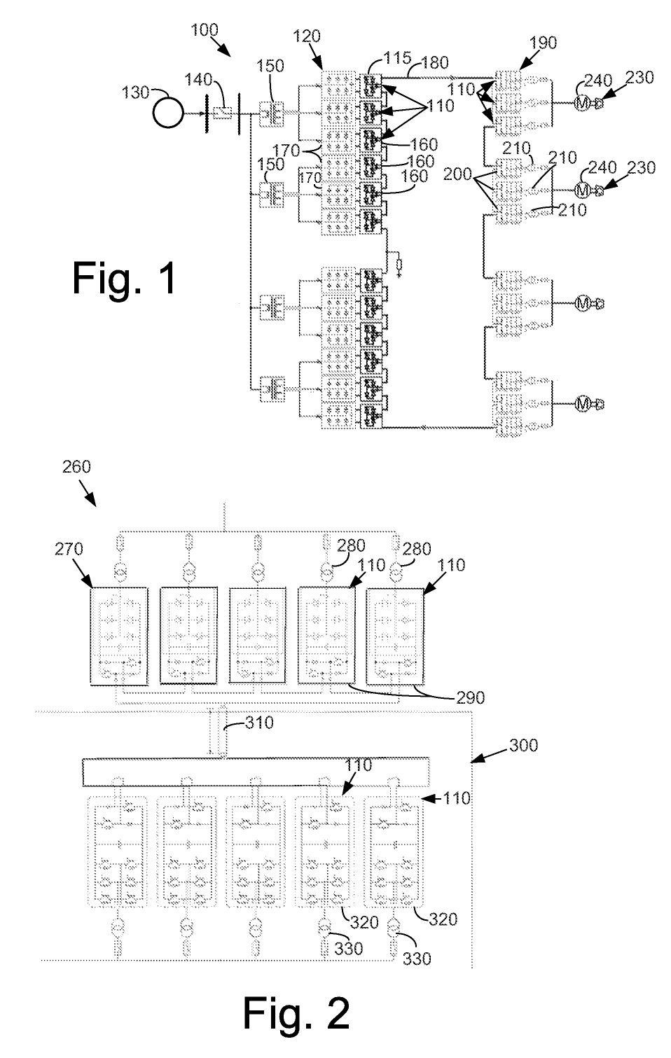

Referring now to the drawings, in which like numerals refer to like elements throughout the several view, FIG. 1 shows an example of a marinized high power HVDC system 100. The high power HVDC system 100 may include a number of modular stacked power converters 110. As will be described in more detail below, these modular stacked power converters 110 may include AC. to DC, DC to DC, DC to AC, and the like. Any type and any number of modular stacked power converters 110 may be used herein in any configuration. The modular stacked power converters 110 may have a converter potential 115. Other types of marinized high power HVDC systems also may be used herein.

FIG. 1 shows an example of an onshore module 120 of the marinized high power HVDC system 100. The onshore module 120 also may be installed on a platform such as an existing oil platform. The onshore module 120 may be connected with an AC power source 130 via a switch gear 140. Any type of AC power source 130 may be used herein such as a turbine or other types of power generation equipment. The AC power source 130 may be in connection with a number of onshore transformers 150. Any number of onshore transformers 150 may be used. The onshore transformers 150 may be polygons transformer and the like.

Each of the transformers 150 may be in connection with a number of the modular stacked power converters 110. In this example, the modular stacked power converters 110 may take the form of a number of AC to DC power converters 160. Any number or configuration of the AC to DC power converters 160 may be used herein. The AC to DC power converters 160 convert the AC current to high voltage DC current. A number of chopper modules 170 may be used with the AC to DC power converters 160. The chopper modules 170 may be configured to operate as bypass switches if necessary. The AC to DC power converters 160 may be in connection with one or more high voltage direct current (HVDC) buses or cables 180. Other configurations also may be used herein.

FIG. 1 also shows an example of a sub-sea module 190 of the marinized high power HVDC system 100. The sub-sea module 190 may include a number of modular stacked power converters 110 in connection with the HVDC cable 180. In this example, the modular stacked power converters 110 may be a number of DC to AC power converters 200. Any number or configuration of the DC to AC power converters 200 may be used herein. The DC to AC power converters 200 convert the high voltage DC current to an AC current. Any number of the chopper modules 170 may be used. The DC to AC power converter modules 200 may be in connection with a number of sub-sea transformers 210. Any number of the sub-sea transformers 210 may be used. Other DC to AC power conversion configurations may be used herein.

FIG. 1 also shows an example of a load module 230 of the marinized high power HVDC system 100. The load module 230 also may be in connection with a HVDC power transmission ring and the like and may include a number of sub-sea loads 240. Any number or type of sub-sea load 240 such as a motor may be used herein. The load module 230 also may include a number of the modular stacked power converters 110. Other configurations and other components may be used herein.

FIG. 2 shows an example of a low power HVDC system 260. The low power HVDC system 260 also may include an onshore module 270. The onshore module 270 also may be installed on a platform such as an oil platform. The onshore module 270 may include a number of onshore transformers 280 in connection with a number of DC to DC converters 290. The DC to DC converters 290 may reduce the medium or high voltage DC power to a lower voltage DC power that is suitable for use with corresponding sub-sea loads. The low power HVDC system 100 also may include a sub-sea module 300. The sub-sea module 300 may be in communication with the onshore module 270 via a HVDC cable 310 and the like. The sub-sea module 300 may include a number of the modular stacked power converters 110. In this example, the modular stacked power converters 110 may be in a form of a number of DC to AC converters 320. The DC to AC converters 320 may be connected to a load via a number of sub-sea transformers 330. Other configurations may be used herein.

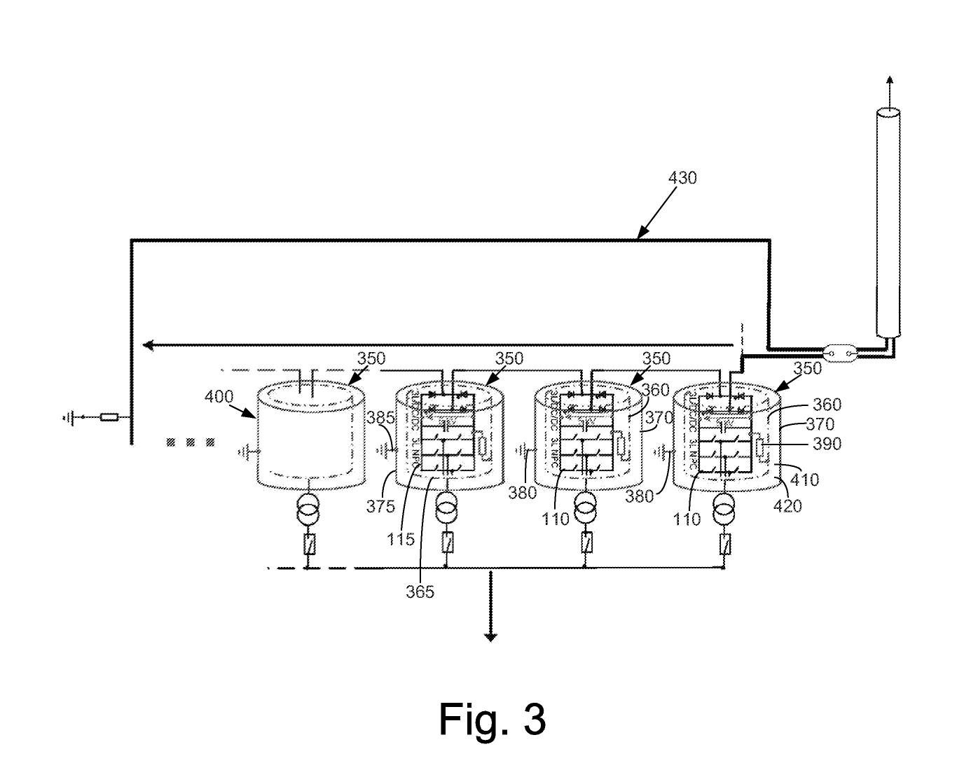

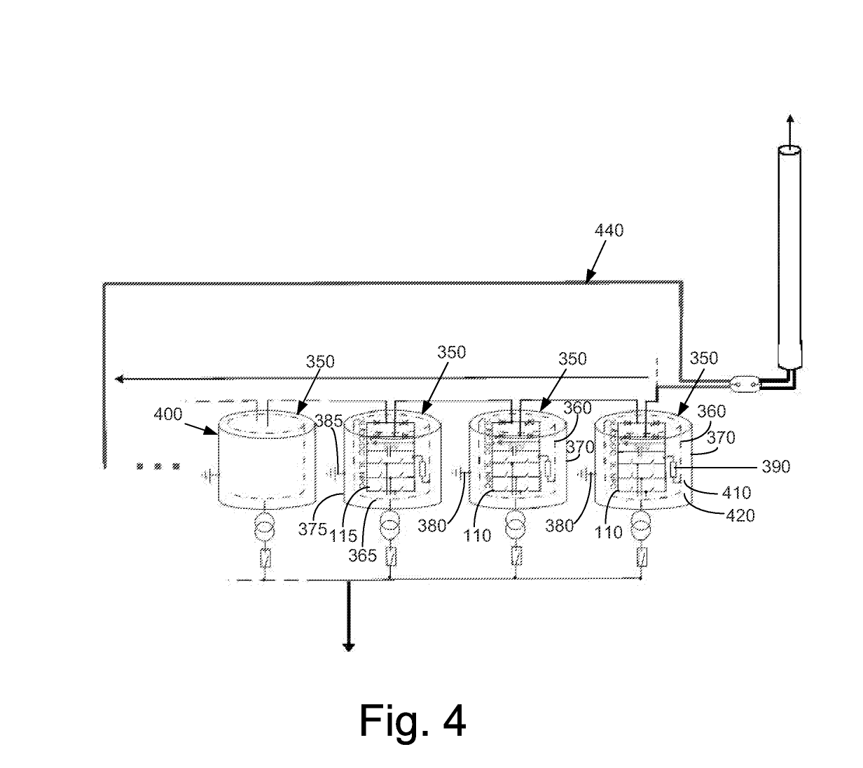

FIGS. 3 and 4 show a number of examples of modular stacked power converter vessels 350 as may be described herein. Each modular stacked power converter vessels 350 may include an inner container 360 and an outer container 370. The inner container 360 and the outer container 370 may be made out of steel and the like. Any type of the modular stacked power converters 110 or a similar device may be positioned within the inner container 360. The modular stacked power converters 110 may include a converter potential 115. The converter potential includes a DC high voltage. The inner container 360 may be at a first potential 365. The first potential 365 may be the same or a similar DC high voltage as the converter potential 115 of the enclosed modular stacked power converter 110. The outer vessel 370, however, may be connected to a ground 380 and thus be at a second potential 375, e.g., at a same ground potential 385 as the surrounding sea water. The outer vessel 370 may contain additional components such as the transformers and the circuit breakers shown in FIGS. 3 and 4 and otherwise.

A cooling system 390 may be positioned between the inner container 360 and the outer container 370 and in connection with the modular stacked power converter 110. The cooling system 390 as positioned inside the inner container 370 may not be exposed to higher potential differences as compared to standard drive systems. Other configurations and other components may be used herein.

The shape of the modular stacked power converter vessel 350 may accommodate the pressures of deep-sea applications such as by using a spherical or a cylindrical shape 400. Other shapes and/or combinations of shapes may be used herein. The inner container 360 and the outer container 370 may define a space 410 therebetween. The space 410 may be filled with a medium 420 such as an insulating material with high mechanical strength, e.g., an epoxy resin or a glass fiber reinforced plastic. The medium 420 also may be a gas with an optimum voltage withstanding capability, e.g., an insulating oil, sulfur hexafluoride (“SF6”), and the like. The medium 420 also may provide sufficient thermal conductivity, i.e., transfer of heat created by electrical losses to the outer container 370. Alternatively, the heat transfer may be provided by cooling tubes with a suitable cooling fluid, e.g., de-ionized water, where the cooling system is designed to withstand the DC high voltage that exists between the inner and the outer vessels. The space 410 may have any desired size. Other types of mediums 420 may be used herein.

The maximum nominal voltage difference between the components within the inner container 360 may be limited to few kilovolts only such that standard drive components may be used. Specifically, the electrical designs may be identical for all components, independent from the high voltage potential of the components against earth. High voltage may exist only between the surfaces of the inner container 360 and the outer container 370 that have a high voltage optimized design and, particularly, equal distances therebetween.

FIG. 3 shows the use of the modular stacked power converter vessels 350 in a unipolar HVDC transmission 430. FIG. 4 shows the use of the modular stacked power converter vessels 350 for a bipolar HVDC transmission 440. Any number of the modular stacked power converter vessels 350 may be used herein in any configuration and in communication with any type of HVDC power source on the onshore end and any type of AC or DC power distribution systems on the sub-sea end or otherwise. Any mode of transmission may be used herein.

The modular stacked power converter vessels 350 thus provide optimized packaging and grounding systems and methods for marinized modular stacked HVDC systems. The modular stacked power converter vessels 350 achieve optimum power delivery with low system costs and complexity, high system reliability and maintainability, high efficiency, and high power density. The modular stacked power converter vessels 350 may operate with low or high power, over long or short distances, and for any type or number of loads.

It should be apparent that the foregoing relates only to certain embodiments of the present application and that numerous changes and modifications may be made herein by one of ordinary skill in the art without departing from the general spirit and scope of the invention as defined by the following claims and the equivalents thereof.

I claim:

1. A modular stacked power converter vessel, comprising:
an inner container;
a modular stacked power converter positioned within the inner container;
the inner container comprising a first potential; and
an outer container;
the outer container surrounding the inner container and comprising a second potential.

2. The modular stacked power converter vessel of claim 1, wherein the modular stacked power converter comprises a converter potential and wherein the first potential comprises the same or a similar converter potential.

3. The modular stacked power converter vessel of claim 1, wherein the second potential of the outer container comprises a ground potential.

4. The modular stacked power converter vessel of claim 1, wherein the outer container comprises a ground.

5. The modular stacked power converter vessel of claim 1, wherein the first potential is greater than the second potential.

6. The modular stacked power converter vessel of claim 1, further comprising a cooling system positioned between the outer container and the inner container and in connection with the modular stacked power converter.

7. The modular stacked power converter vessel of claim 1, wherein the outer container comprises a spherical or cylindrical shape.

8. The modular stacked power converter vessel of claim 1, wherein the inner container and the outer container comprise a space therebetween with a voltage withstanding medium within the space.

9. The modular stacked power converter vessel of claim 8, wherein the voltage withstanding medium comprises an epoxy resin, a glass fiber reinforced plastic, an insulating oil, or a sulfur hexafluoride.

10. The modular stacked power converter vessel of claim 1, further comprising a plurality of modular stacked power converter vessels configured for unipolar high voltage direct current transmission.

11. The modular stacked power converter vessel of claim 1, further comprising a plurality of modular stacked power converter vessels configured for bipolar high voltage direct current transmission.

12. A modular stacked power converter vessel, comprising:
an inner container;
a modular stacked power converter positioned within the inner container;
the modular stacked power converter comprising a converter potential;
the inner container comprising about the converter potential; and
an outer container;
the outer container surrounding the inner container and comprising a ground potential.

13. The modular stacked power converter vessel of claim 12, wherein the outer container comprises a ground.

14. The modular stacked power converter vessel of claim 12, further comprising a cooling system positioned between the outer container and the inner container and in communication with the modular stacked power converter.

15. The modular stacked power converter vessel of claim 12, wherein the outer container comprises a spherical or cylindrical shape.

16. The modular stacked power converter vessel of claim 12, wherein the inner container and the outer container comprise a space therebetween with a voltage withstanding medium within the space.

17. The modular stacked power converter vessel of claim 16, wherein the voltage withstanding medium comprises an epoxy resin, a glass fiber reinforced plastic, an insulating oil, or a sulfur hexafluoride.

18. The modular stacked power converter vessel of claim 12, further comprising a plurality of modular stacked power converter vessels configured for unipolar high voltage direct current transmission.

19. The modular stacked power converter vessel of claim 12, further comprising a plurality of modular stacked power converter vessels configured for bipolar high voltage direct current transmission.

20. A marinized high voltage direct current system for sub-sea DC power transmission and distribution, comprising:
a first module at a first potential;
a second module at a second potential; and
an electrical connection between the first module and the second module;
the first module and the second module both comprising a plurality of modular stacked power converters therein;
wherein each of the plurality of modular stacked power converters is positioned within a modular stacked power converter vessel; and
wherein the modular stacked power converter vessel comprises an inner container within an outer container.
